(19) United States
(12) Patent Application Publication
(10) Pub. No.: US 2026/0120758 A1
(43) Pub. Date: Apr. 30, 2026

(54) STORAGE CIRCUIT

(71) Applicant: Arm Limited, Cambridge (GB)

(72) Inventors: Rajiv Kumar SISODIA, Bangalore (IN); Yew Keong CHONG, Austin, TX (US); Prashantkumar Jayantilal VAGHASIA, Austin, TX (US); Vishal Vinay THAKRE, Austin, TX (US); Disha SINGH, Bangalore (IN); Jaspreet SINGH, Bangalore (IN)

(21) Appl. No.: 18/925,460

(22) Filed: Oct. 24, 2024

(51) Int. Cl. G11C 11/419; H01L 25/18

(52) U.S. Cl. CPC G11C 11/419; H10W 90/00

(57) ABSTRACT

Storage circuitry including a bitcell array including a plurality of bitcells arranged in one or more columns and one or more rows, a first bitline to select bitcells of a first column, a first dummy bitline associated with the first bitline, where the first dummy bitline includes dummy control circuitry having a plurality of electrical paths arranged between the dummy bitline and a first voltage level, where a first electrical path of the plurality of electrical paths includes a first load electrically couplable thereto to control a property of a dummy bitline signal.

### TECHNICAL FIELD

The present techniques relate to a storage system and circuits therefor.

### BACKGROUND

A typical storage device has an array of bitcells (or storage cells) arranged as a plurality of rows and columns, with wordlines (WLs) being coupled to the rows and bitlines (BLs) being coupled to the columns. Access circuitry then performs read and write access operations in respect of bitcells selected via an associated WLs and BLs. Control circuitry is used to control operation of the access circuitry when performing such access operations.

Since the bitcells behave differently to the logic gates used to construct the access circuitry and control circuitry, it is known to use a self-timed path (STP) circuitry for reliable access operations.

### SUMMARY

The present techniques relate to improving STP circuitry.

In a first approach there is provided storage circuitry comprising a bitcell array comprising a plurality of bitcells arranged in one or more columns and one or more rows; a first bitline to select bitcells of a first column, a first dummy bitline associated with the first bitline, where the first dummy bitline comprises dummy control circuitry having a plurality of electrical paths arranged between the dummy bitline and a first voltage level, where a first electrical path of the plurality of electrical paths comprises a first load electrically couplable thereto to control a property of a dummy bitline signal.

In a further approach there is provided a method of operating storage circuitry, the storage circuitry including: a bitcell array comprising a plurality of bitcells arranged in one or more columns and one or more rows; a first bitline to select bitcells of a first column, a first dummy bitline associated with the first bitline, where the first dummy bitline comprises dummy control circuitry having a plurality of electrical paths arranged between the dummy bitline and a first voltage level, where a first electrical path of the plurality of electrical paths comprises a first load electrically couplable thereto; the method comprising: enabling the first electrical path to control a property of a dummy bitline signal.

In a further approach there is provided a storage system comprising: providing storage circuitry with a bitcell array comprising a plurality of bitcells arranged in one or more columns and one or more rows; coupling a first bitline to the first column for selecting bitcells of a first column, providing a first dummy bitline associated with the first bitline; providing dummy control circuitry having a plurality of electrical paths arranged between the dummy bitline and a first voltage level, where a first electrical path of the plurality of electrical paths comprises a first load electrically couplable thereto to control a property of a dummy bitline signal.

In a further approach there is provided a system comprising: the above circuitry, implemented in at least one packaged chip; at least one system component; and a board, wherein the at least one packaged chip and the at least one system component are assembled on the board.

In a further approach there is provided a chip-containing product comprising the above system assembled on a further board with at least one other product component.

In a further approach there is provided a non-transitory computer-readable medium to store computer-readable code for fabrication of the above circuitry.

### BRIEF DESCRIPTION OF THE DRAWINGS

Implementations of the disclosed technology will now be described, by way of example only, with reference to the accompanying drawings, in which:

FIG. 1 shows a simplified view of a storage system in accordance with the present techniques;

FIG. 2a shows a simplified diagram of an example self-timed path circuitry;

FIG. 2b shows a further simplified diagram of an example self-timed path circuitry;

FIG. 3a shows a simplified diagram of a self-timed path circuitry in accordance with the present techniques;

FIG. 3b shows a further simplified diagram of self-timed path circuitry in accordance with the present techniques;

FIG. 4a is a graph which illustratively depicts EMA measurements for circuits with and without an additional load;

FIG. 4b is a table showing step sizes between EMA measurements for circuits with and without an additional load;

FIG. 5 is a flow diagram of a method for providing a storage system in accordance with the present techniques;

FIG. 6 is a flow diagram for providing a storage system having self-timed path circuitry in accordance with the present techniques;

FIG. 7 shows a system and a chip-containing product.

### DETAILED DESCRIPTION

Various implementations described herein are directed to dummy bitline (DBL) circuitry for a storage circuit and such applications.

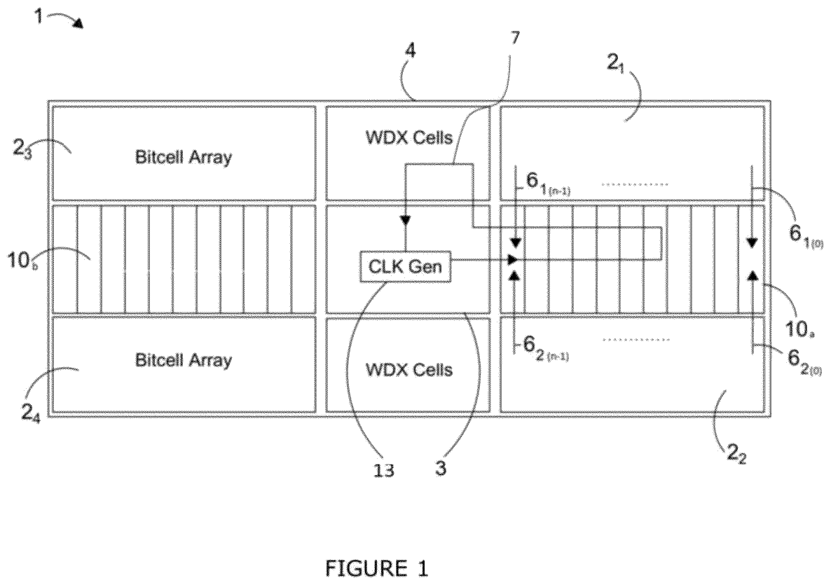

FIG. 1 shows a simplified view of a storage system 1 (or storage circuitry).

The storage system 1 is depicted as a “butterfly” architecture having four bitcell arrays, two (2₁ and 2₂) on the right-hand side of FIG. 1 and two (2₃ and 2₄) on the-left hand side of FIG. 1, with control circuitry 3 and wordline selection (WDX) circuitry or cells 4 arranged at the mid-section of the storage system 1.

It will be appreciated the storage system 1 is not limited to the “butterfly” architecture depicted in FIG. 1, and the storage system may have any number of bitcell arrays as required.

Each bitcell array 2ₙ comprises a plurality of bitcells 5 arranged in a plurality of rows and columns therein, each row of a particular bitcell array 2ₙ being coupled to an associated word line (WL) (not shown in FIG. 1) to provide a wordline (wl) signal to select the bitcells coupled thereto in a read or write operation, and each column of bitcells of a particular bitcell array 2ₙ being coupled to an associated bitline (BL) to provide a bitline (bl) signal to select the bitcells electrically coupled thereto in a read or write operation. In embodiments each bitcell 5 in a bitcell array 2ₙ may be accessed with a wordline WL and complementary bitlines BL, NBL, where a differential between the complementary bitlines may be used for read and write operations. For ease of description only the BL (and not NBL) will be described hereafter.

Each bitcell 5 in a bitcell array 2ₙ may be configured to store at least one data bit value (e.g., a data value related to a logical ‘0’ or ‘1’). Each row of bitcells in the array of bitcells may include any number of bitcells or memory cells arranged in various configurations, such as, e.g., a two-dimensional (2D) memory array having columns and rows of multiple bitcells arranged in a 2D grid pattern with 2D indexing capabilities. Further, each bitcell may be implemented, e.g., with random access memory (RAM) circuitry, or some other type of volatile type memory. For instance, each memory cell may include a multi-transistor static RAM (SRAM) cell, including various types of SRAM cells, such as, e.g., 6T CMOS SRAM and/or other types of complementary MOS (CMOS) SRAM cells, such as, e.g., 4T, 8T, 10T, or more transistors per bit.

Generally, static RAM bitcells may include 6T bitcells, which may have access ports controlled by wordlines (WLs). In some instances, SRAM) bitcells may be implemented with a 5T bitcell, 4T 2R bitcell, or various other types of CMOS SRAM cells, such as, e.g., 8T, 10T or more transistors per bit. Further, multi-wordlines may result in multiple access ports into each of the bitcells. Since there are multiple access ports, the multi-ports access devices may be varied within each bitcell so that some access devices (by port) are NFETs and some access devices by port are PFETs. Although these may be effectively varied within each single bitcell, their number of ports may not be easily divided into equal capacitance and/or power. Thus, although these multi-ports transistor types may vary within each bitcell, there may also be a need to have a variation between arrays as in a left half array and a right half array.

The storage system 1 includes wordline selection (WDX) circuitry or cells 4 which may include row decoder circuitry (not shown) and wordline driver circuitry (not shown). In some instances, the row decoder may be used to access each bitcell of a bitcell array 2ₙ via a selected wordline that is driven by the wordline driver circuitry. In the present embodiments the combination of the row decoder and the wordline driver are depicted as WDX cells 4.

Furthermore, the storage system includes bitline or column selection circuitry 10a/b which may include column read (CR) and column write (CW) access or multiplexer (MUX) devices for controlling provision of bitline signals via bitlines to select a required column of bitcells responsive to signals from the control circuitry 3.

As an illustrative example, column selection circuitry 10a will control the CR or CW devices to provide bl signals to select a particular column of bitcells via an associated bitlines BL 6₁₍₀₎ to 6₁₍ₙ₋₁₎ for the columns in the bitcell array 2₁. As a further illustrative example, column selection circuitry 10a will provide bl signals to select a particular column of bitcells via an associated bitlines BL 6₂₍₀₎ to 6₂₍ₙ₋₁₎ for the columns in the bitcell array 2₂. Similarly, the bitcell arrays 2₃ and 2₄ may also receive bitline signals from column selection circuitry 10_{b} via respective bitlines.

The control circuitry 3 may include clock generation circuitry 13 that may receive a clock signal CLK (e.g. an external clock signal) and may provide an internal clock signal as a global timing pulse (gtp) signal to various functional units to initiate (or control) a particular operation, such as initiating read or write operations. The gtp (or an inverted or modified form of it i.e. ngtp or ngtpa) may, for example, be provided to sense amplifier circuitry and latch circuitry as a latch control signal to, for example, cause the latch circuit to output a latch signal QA to initiate a read or write operation.

The clock generation circuitry 3 comprises STP clock generation circuitry which may receive one or more signals via a self-time path (STP), a portion of which is depicted in FIG. 1.

The STP may be used to control the timing of sense amplifiers and latches for reading or writing to a bitcell array within the storage system 1, to ensure that the sense amplifier circuitry and latch circuitry operate at the correct time to provide a reliable read or write operation.

The STP may comprise one or more dummy bitlines (DBL) for associated BLs and one or more dummy wordlines (DWL) for associated WLs, where a dbl signal on the DBL may be used to control read or write operations. Thus controlling the properties of dbl signals on the STP is important for providing reliable read and write operations.

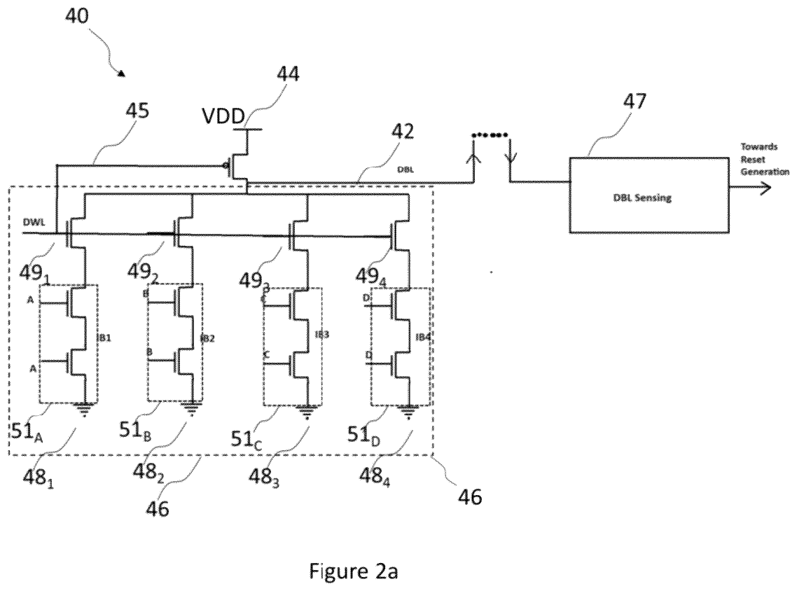

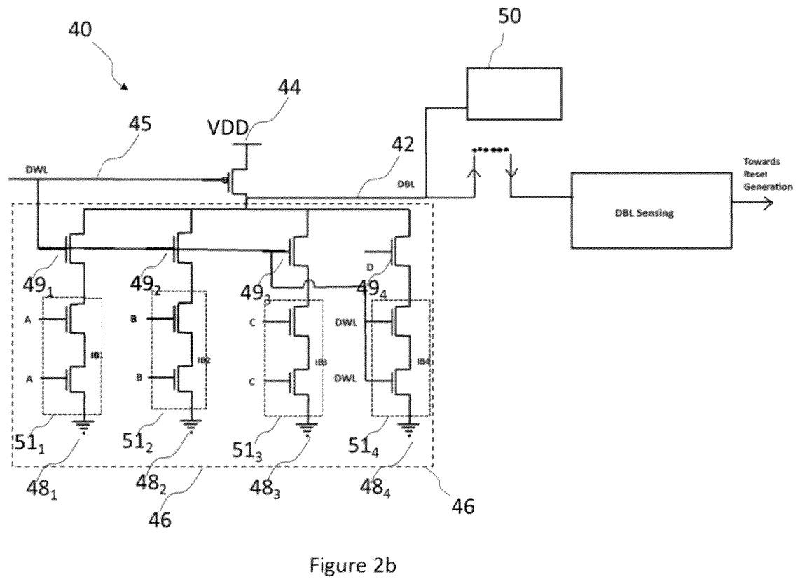

FIG. 2a shows a schematic diagram of STP circuitry 40 which comprises a dummy bitline (DBL) 42 that provides a dummy bitline signal (dbl). A property of an output of the DBL 42 (i.e. a dbl signal) may be sensed by DBL sensing logic 47, whereby the DBL sensing logic 47 may operate responsive to the dbl signal. For example, when the dbl signal discharges below a certain (e.g. threshold) level, the DBL sensing logic 47 may provide a “reset” signal to controller circuitry (not shown in FIG. 2a), where the controller circuitry is to, responsive to the “reset” signal, assert a sense amplifier signal to enable various sense amplifiers and circuits in the appropriate functional units for reading or writing data to the bitcell array. Thus, the timing of the reset signal is important for correct (accurate) access (read or write) operations. An access margin may be taken to be the time for the dbl signal to discharge to a level (e.g. threshold level) at which the DBL sensing circuitry generates the “reset” signal.

The peripheral circuitry (e.g. including the bitlines and circuitry along the STP path) may operate in different voltage domains (e.g. from 400 mv to 1.2V) dependent on user requriements, where a desired access margin may be shorter when the operating in a relatively high voltage domain (e.g. 1.2v) than when operating in a relatively low voltage domain (e.g. 400 mv).

DBL 42 comprises a transistor 44 arranged between a first voltage level (depicted as VDD) and the DBL 42 where, in FIG. 2a, the transistor 44 is a PMOS transistor which is controlled responsive to a dummy wordline signal (dwl) on DWL. When the PMOS transistor is turned on the DBL may be charged to the voltage level of the associated bitline, and when turned off the DBL may discharge, where the DBL sensing logic 47 is to generate the reset signal responsive to the dbl signal.

There may exist difference(s) in properties or characteristics of the bl and dbl signals (i.e. differences in the behaviour of the BL and associated DBL) which may be the result of, for example, process variations in the circuitry of the storage system during manufacture. The divergence may result in degraded performance due to unreliable or inefficient read or write operation across the different voltage domains. As an illustrative example, when the dbl signal discharges faster than the associated BL then the resulting reset signal may cause the access operation to complete too early, and there may be an incorrect read or write, at least, a correct read or write operation may not be guaranteed. Thus, some storage systems provide an increased access margin by delaying the discharge of the dbl signal for different voltage domains.

To achieve such a delay, the DBL circuitry 40 further comprises dummy control circuitry (DCC) 46, which may be used to adjust a property of a dbl signal to control the duration of the access margin.

DCC 46 comprises a plurality of discharge paths, depicted in the figures below as stacks (or groups) of transistors 48₁₋₄ (four of which are depicted in FIG. 2a), where the transistors in each stack are arranged in series between a second voltage level (Depicted as a ground voltage (or VSS)) and DBL 42. Each stack of transistors is arranged in parallel with respect to the other stacks of transistors.

A first transistor 49₁₋₄ in each stack 48₁₋₄ is controlled responsive to the dwl signal, whilst the remaining transistors in each stack, which comprise pairs of NMOS EMA (extra margin adjustment) transistors 51_{A}-51_{D} arranged in series in the respective stacks 48₁₋₄, and are controlled responsive to EMA (or nEMA, where the nEMA control signal is an inverted version of the EMA signal) control signals, labelled A, B, C & D.

The EMA control signals A-D may be provided as an external input to EMA pins at the storage system, for example from an application running in an associated central processor unit or graphics processor unit (not shown), dependent on required EMA settings (e.g. desired access margin) for each different voltage domain in which the storage system is to operate.

When the dwl signal is provided as “LOW” or “0” on the DWL 45 it will enable (turn on) the PMOS transistor 44 (and NMOS transistors 49₁-49₄ will be disabled or (turned off)) and the DBL will be charged via the first voltage based on the state of the associated BL.

When the dwl signal is provided as “HIGH” or “1”, NMOS transistors 49₁-49₄ will be enabled (and PMOS transistor 44 will be disabled), and the DBL 42 will discharge through one or more of the stacks of transistors 48₁₋₄ that have the NMOS EMA transistors 51_{A}-51_{D} enabled responsive to the EMA control signals A-D being asserted.

Discharging the DBL causes the DBL sensing circuitry 47 to generate a reset signal (e.g. when the dbl signal is discharged below a threshold level), which is provided to controller circuitry (not shown in FIG. 2a/b). For example, when the reset signal from the sensing circuitry 47 is LOW, the controller circuitry may de-assert the internal clock signal gtp.

The EMA control signals may be provided as inputs based on an EMA address, where the EMA control signals will determine the number of stacks that are enabled as a discharge path. Increasing the number of stacks through which the DBL discharges will increase the discharge speed (reduce the access margin) and decreasing the number of stacks through which the DBL discharges will decrease the discharge speed (increase the access margin). Thus, the amount of stacks 48₁₋₄ that are enabled can be changed dependent on the EMA settings required, where more stacks will be enabled when operating in a higher voltage domain compared to when operating in a lower voltage domain.

Customers may require a storage system to operate in accordance with different EMA settings (e.g. required access margins for different voltage domains) for performance, where operating in accordance with first EMA settings (e.g. in a higher voltage domain) may provide for faster memory, whilst operating in accordance with second EMA settings (e.g. in a lower voltage domain) may be used to save power but reduce performance.

The stacks can then be enabled responsive to the dwl and the EMA control signals dependent on the required EMA settings. For example, when the storage system is to operate in accordance with a first EMA setting one stack 48₁ may be enabled to discharge the DBL. When the storage system is to operate in accordance with a second EMA setting the other stacks may be enabled to discharge the DBL.

In FIG. 2a the access margin that can be achieved by a particular stack may be dependent on the properties or characteristics of transistors in that stack (e.g. the voltage threshold V_{TH} of the transistors).

Further control of the access margin may be achieved by turning on or off the different stacks. However, the maximum access margin that can be achieved by enabling/disabling the different stacks will be limited by the properties of the transistors in the stacks.

As depicted in FIG. 2b, to achieve an increased (longer) access margin load circuitry 50 may be electrically coupled the DBL 42 to provide an additional load on the DBL to slow discharge of the dbl signal. The load circuitry 50 may comprise a capacitive, resistive and/or inductive element(s) or component(s), where the properties of the load circuitry 50 provided on the DBL may be based on modelling or testing during a design phase.

In the illustrative example, of FIG. 2b, the load circuitry is optimised for the fourth stack 48₄ when operating in accordance with a particular EMA setting (e.g. to achieve an optimum access margin for that particular voltage domain), but the load circuitry 50 electrically coupled to the DBL will also impact/affect discharging of the DBL via the other stacks 48₁₋₃ so may negatively impact the access margins when operating in those other voltage domains.

Thus, operational efficiency may reduce when operating the storage system with the load circuitry 50 on the DBL across different voltage domains.

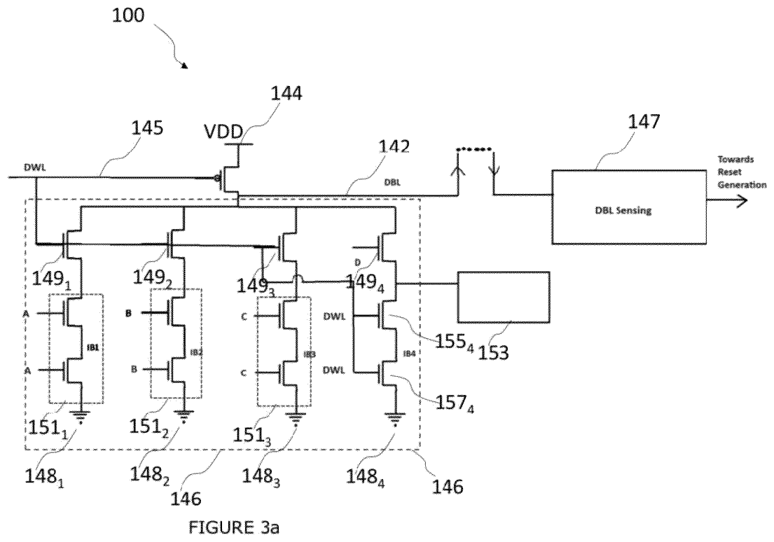

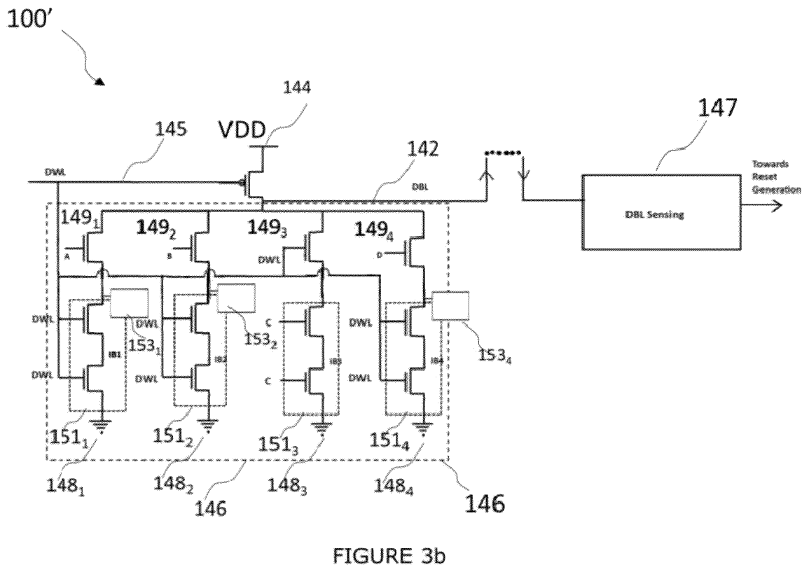

FIG. 3a shows a schematic diagram of STP circuitry 100 in accordance with an embodiment of the present techniques; and FIG. 3b shows a schematic diagram of STP circuitry 100′ in accordance with a further embodiment of the present techniques.

The STP circuitry 100/100′ is similar to that depicted in FIG. 2a/2b and comprises a dummy bitline (DBL) 142 that provides a dummy bitline signal (dbl) to DBL sensing circuitry 147, which is to operate responsive to the dbl signal.

DBL 142 comprises a transistor 144 arranged between a first voltage level (depicted as VDD) and the DBL 42 where, in FIG. 3a/3b, the transistor 144 is depicted as a PMOS transistor which is controlled responsive to the dummy wordline signal (dwl). In embodiments, the first voltage level may be between, for example, 0.4v and 1.2v, where the first voltage level may be adjusted dependent on the voltage domain in which the storage system is required to operate. The first voltage may be adjusted in steps, where each voltage domain may be required to operate in accordance with EMA settings (e.g. desired access margin) for each different voltage domain.

DBL circuitry 100 further comprises DCC 146 comprising a plurality of electrical paths for the DBL. In the illustrative examples of FIGS. 3a and 3b, the electrical paths comprise discharge paths depicted as stacks (or groups) of transistors 148₁₋₄ (four of which are depicted in FIG. 3a/3b), where the transistors in each stack are arranged in series between a second voltage level (Depicted as ground (e.g. VSS)) and DBL 142. In the following embodiments the discharge paths 148₁₋₄ are described as stacks of three transistors but, in accordance with the present techniques, the discharge paths are not limited to stacks of three transistors, and may comprise additional or alternative components or circuitry therealong. The transistors in each stack 148₁₋₄ in FIGS. 3a & 3b are depicted as NMOS transistors, although the claims are not limited in this respect.

Each stack in the stack of transistors 148₁₋₄ is arranged in parallel with respect to the other stacks, where each stack is individually controllable to provide a discharge path between the DBL and ground (VSS).

In FIG. 3a a first transistor 149₁₋₃ in each stack 148₁₋₃ is controlled responsive to the dwl signal, whilst the remaining transistors in the respective stacks 148₁₋₃, which comprise pairs of EMA transistors 151_{A}-151_{C} arranged in series, where the EMA transistors 151_{A}-151_{C} are controlled responsive to respective EMA (or nEMA) control signals A-C. The EMA (or nEMA) control signals may be selected based on an EMA address dependent on the number of stacks to be enabled (i.e. dependent on the required discharge strength of the EMA settings).

In contrast to the STP circuitry depicted in FIGS. 2a and 2b, the DCC 146 in FIG. 3a comprises additional load circuitry 153 (DCCLC) electrically couplable to the fourth stack 148₄ between the first transistor 149₄ and second transistor 155₄ thereof. The DCCLC 153 may comprise a resistive, capacitive and/or inductive load on the DBL to change a property of the dbl signal (e.g. the rate of discharge). However, the additional load provided by the DCCLC 153 will not affect the dbl signal when discharging through one or more of the other stacks 148₁₋₃.

In embodiments the load provided by the DCCLC 153 may be adjustable (configurable or programmable (e.g. via hardware and/or software)) to control the rate of discharge of the dbl signal as required by, for example, by design or user requirements.

The first transistor 149₄ in the stack 148₄ is controlled responsive to an EMA control signal D which, as with the control signals A-C above, may be selected based on an EMA address dependent on requirements. The EMA control signals A-D may be provided as external inputs to EMA pins at the storage system 100, for example from an application running in an associated central processor unit or graphics processor unit (not shown). The second transistor 155₄ and third transistor 157₄ in the stack 148₄ are controlled responsive to the dwl signal.

The DCCLC 153 provides an additional load on the 142 on the discharge path where, when a stack having the DCCLC electrically coupled thereto is enabled, the DCCLC will be discharged before the DBL is discharged, thereby delaying the discharge of the DBL and delaying the reset signal from the sensing circuitry.

The configuration depicted in FIG. 3a provides for selecting (enabling) one or more of the stacks 148₁₋₃ to provide a discharge path between the DBL 142 and a voltage level (e.g. ground) independent of the load provided by the DCCLC 153 on the fourth transistor stack 148₄, and further provides for selecting (enabling) the stack 148₄ having the DCCLC 153 to provide a discharge path between the DBL 142 and ground in accordance with the DCCLC 153.

Looking at FIG. 3a, when operating in accordance with a first EMA setting (e.g. providing an access margin when operating in a first voltage domain), the first to third transistor stacks 148₁₋₃ may be enabled (and the fourth transistor stack 148₄ disabled) to discharge the DBL through the first to third transistor stacks 148₁₋₃ in accordance with that first EMA setting.

When the need arises for the storage system to operate in accordance with a different EMA setting (e.g. providing a different access margin when operating in the first voltage domain or a different voltage domain), the fourth transistor stack 148₄ may be enabled (and the first to third stacks 148₁₋₃ disabled) to discharge the DBL through the fourth transistor stack 148₄. Thus, the DCCLC 153 will not affect the discharge of the DBL through the first to third stacks 148₁₋₃ when operating in accordance with the first EMA setting, and using the DCCLC 153 in this manner provides flexibility to independently tune each discharge path across multiple EMA settings (e.g. across one or more voltage domains).

As the DCCLC 153 is programmable, the load may be adjusted (e.g. increased or decreased) to adjust the properties of the dbl signal as required. Such functionality provides for achieving different access margins using a single stack.

The position of the DCCLC 153 in a stack may also affect the properties of the dbl signal. For example, the discharge rate may be faster when a DCCLC 153 is electrically coupled between the second transistor 155₄ and third transistor 157₄ compared to when the same DCCLC 153 is electrically coupled between the first transistor 149₄ and second transistor 155₄ as depicted in FIG. 3a. In such a configuration the first transistor 149₄ and second transistors 155₄ would be controlled responsive to the EMA (nEMA) control signal, and the third transistor 157₄ would be controlled responsive to the dwl signal.

Furthermore, although the DCCLC 153 in FIG. 3a is depicted as being electrically coupled in the fourth stack 148₄, the claims are not limited in this respect.

As depicted in the DBL circuitry 100′ of FIG. 3b, the DCCLC 153 may be electrically coupled to one or more of the stacks 148₁₋₄, where DCCLC 153₁ is provided in the first stack 148₁, DCCLC 153₂ in the second stack 148₂ & DCCLC 153₄ in the fourth stack 148₄.

Furthermore, adjusting or programming the DCCLC in each stack provides the ability to independently adjust (increase or decrease) the achievable access margins for one or more voltage domains.

Thus providing one or more DCCLCs in the storage system 100/100′ provides for a robust design because the DCCLC provides for independently tuning individual stacks to achieve a desired access margin. Furthermore, the DCCLC provides for a larger access margin step size to be obtained compared to a storage system that does not have a DCCLC.

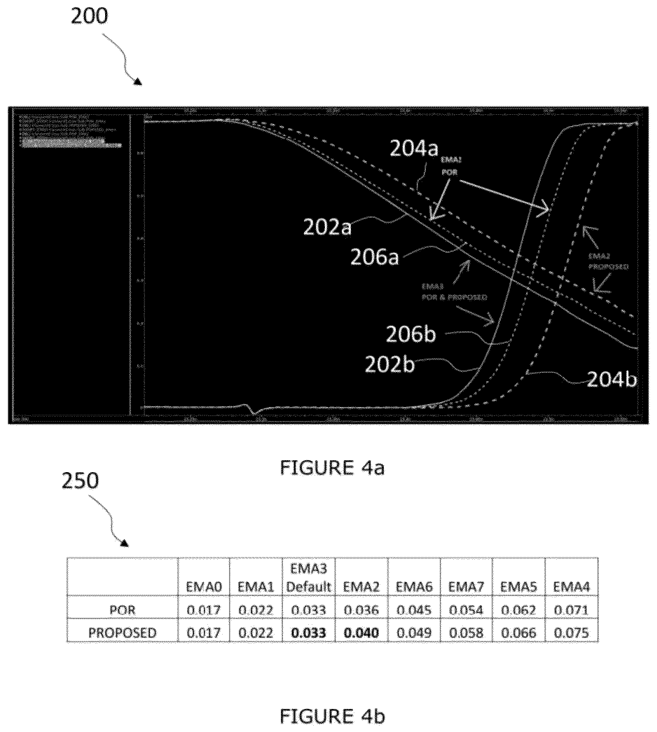

FIG. 4a is a graph 200 which illustratively depicts point of reference (“POR”) EMA measurements for a circuit without a DCCLC and proposed (“PROPOSED”) EMA measurements for a circuit with a DCCLC at two different EMA settings (EMA2 & EMA3). FIG. 4b is a table 250 showing the step sizes between different EMA stages EMA0-EMA7 for the POR and PROPOSED EMA measurements, where the figures were obtained from a compiler. EMA3 is the nominal or default voltage domain (e.g. 0.75v) in Table 4b. EMA0 is the highest voltage domain (e.g. 1.2v), with EMA 1 the next highest voltage (e.g. 0.85v), and EMA 2 is the lowest voltage domain e.g. 0.4v.

EMA4, 5, and 7 may be used as back up or redundancy EMAs which may be used in the event of a fault with the primary EMAs (e.g. EMAs 0-3). There may be a performance penalty incurred when operating in accordance with EMAs 4-7.

The waveform signals 202a, 204a and 206a which are falling represent the discharge of the dbl signal and the waveforms which are rising 202b, 204b and 206b represent the output of the DBL sensing circuitry 147.

In FIG. 4a, the signals 202a/b and 206a/b depict a system without a DCLCC, where an access margin step size from the nominal EMA and the next step size to EMA2 0.036 ns (0.003 ns). In the present illustrative example it is desirable to achieve 40 ns at EMA2, but such an step change in the access margin is not achievable for a system without a DCCLC. The next available EMA option for a system without a DCCLC is EMA6 (45 ns), which would incur a performance penalty.

In contrast, for a system that includes a DCLCC, a step size of 0.007 ns between EMA3 and EMA2 is achievable.

Furthermore, as can be seen in FIG. 4a, the signals for EMA3 202a & b are at the same level for both the POR and PROPOSED measurements when using the system with a DCLCC to obtain the proposed EMA2, which demonstrates that the DCLCC on a discharge path to control the properties (discharge rate) of the dbl signal to achieve a desired access margin for a particular EMA setting does not impact the properties of the dbl signal when discharging via other discharge paths for other EMA settings.

Therefore, the present techniques provide for individually tuning the DBL load for different EMA settings (for one or more voltage domains) without compromising PPA whilst achieving improved EMA step size granularity.

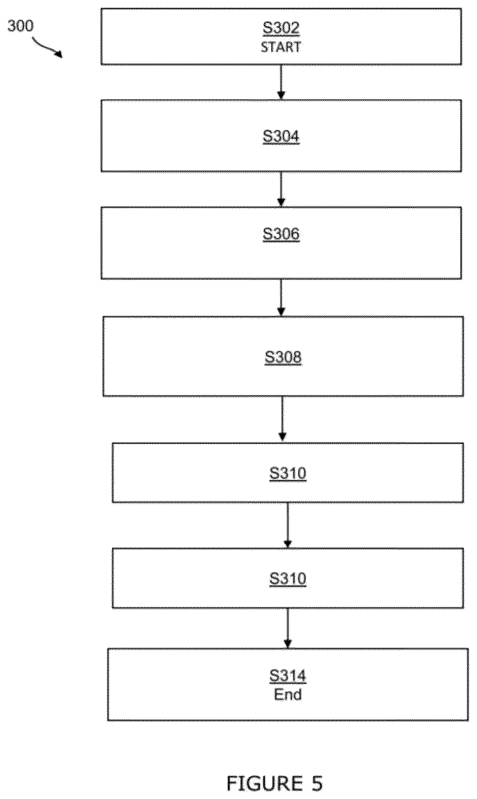

FIG. 5 is a flow diagram of a method 300 for providing a storage system in accordance with the present techniques.

At S302 the method starts.

At S304 an access (e.g. a read or write operation) for a bitcell is initiated by issuing a wl signal to access that particular bitcell on a bitline (BL) to which the bitcell is coupled.

At S306 one or more discharge paths of dummy control circuit (DCC) associated with a dummy bitline (DBL) are programmed in accordance with a required EMA setting (to achieve a particular discharge rate of the dbl signal).

At S308 the DBL is charged to the state of an associated BL responsive to a first (e.g. low) DWL signal.

At S310 the DBL is discharged through the programmed DCC responsive to a second (e.g. high) DWL signal and one or more EMA signals provided to the DCC.

At S312 when the dbl signal is discharged (e.g. to a threshold level), sensing circuitry electrically couplable to the DBL is to provide a signal (e.g. “reset” signal) to controller circuitry to enable various sense amplifiers and circuits in the appropriate functional units for reading or writing data to the bitcell.

At S314 the method ends.

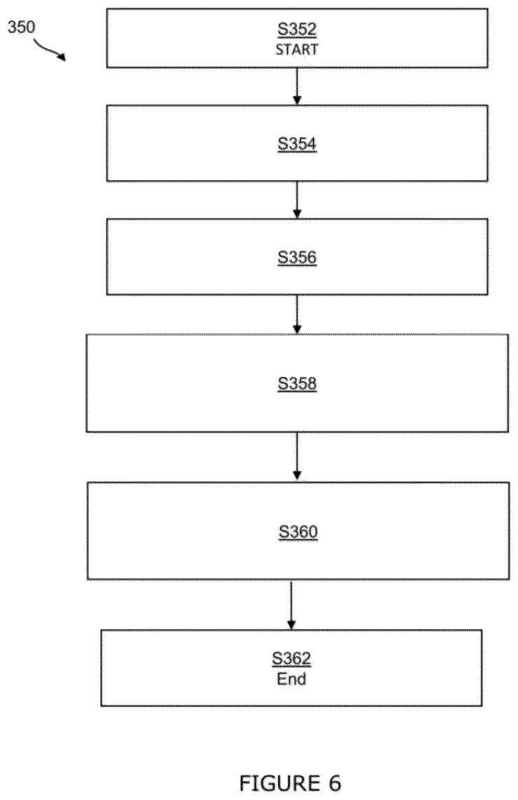

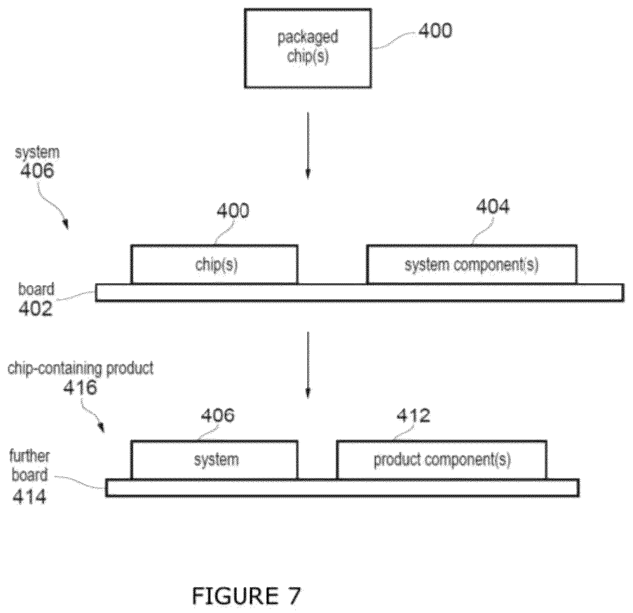

FIG. 6 illustrates a flow diagram of a method 350 for providing a storage system in accordance with various implementations described herein.

It should be understood that even though method 350 may indicate a particular order of operation execution, in some cases, various certain portions of the operations may be executed in a different order, and on different systems. In other cases, additional operations and/or steps may be added to and/or omitted from method 350.

Also, method 350 may be implemented in hardware and/or software. When implemented in hardware, the method 350 may be implemented with various circuit elements, such as described herein above in reference to FIGS. 3a and 3b. When implemented in software, the method 350 may be implemented as a program and/or software instruction process that may be configured for providing DBL design techniques as described herein. Also, if implemented in software, instructions related to implementing the method 350 may be stored in memory and/or a database. For instance, a computer or various other types of computing devices having a processor and memory may be configured to perform method 350.

As described and shown in reference to FIG. 6, method 350 may be utilized for fabricating and/or manufacturing, or causing to be fabricated and/or manufactured, an integrated circuit (IC) that implements STP design schemes and techniques as described herein that are related to providing STP architecture and/or various associated systems, devices, components, circuits and related architecture.

At S352, method 350 starts and at S354 may provide storage circuitry with one or more bitcell arrays, each bitcell array comprising a plurality of storage cells arranged in columns and rows accessible by respective bitlines and wordlines.

At S356, method 350 may provide, for a BL of bitcells, STP circuitry with an associated DBL to provide a dbl signal.

At S358, method 350 may provide a dummy control circuity along the DBL, where the dummy control circuitry provides a plurality of discharge paths from the DBL to the first voltage.

At S360, the method 350 may provide load circuitry along one or more of the plurality of discharge paths, where the load circuitry is to provide for independently tuning the load on the one or more discharge paths. In embodiments, the load circuitry may be programmable.

At S362, method 350 ENDS

In some implementations, the DBL comprising the programmable load provides for tuning the properties of the DBL discharge paths independently of one another. Such functionality provides for achieving increased EMA step size granularity without impacting the properties of other discharge paths in the DCC.

As will be appreciated by one skilled in the art, the present technology may be embodied as a method, a circuit or a computer readable medium comprising data and imperatives to cause construction of a circuit. Accordingly, the present technique may take the form of an entirely hardware embodiment, an entirely software embodiment, or an embodiment combining software and hardware. Where the word “component” is used, it will be understood by one of ordinary skill in the art to refer to any portion of any of the above embodiments.

The present techniques described herein may be operational with numerous general purpose or special purpose computing system environments or configurations. Examples of computing systems, environments, and/or configurations that may be suitable for use with the various technologies described herein include, but are not limited to, personal computers, server computers, hand-held or laptop devices, multiprocessor systems, microprocessor-based systems, set top boxes, programmable consumer electronics, network PCs, minicomputers, mainframe computers, smart phones, tablets, wearable computers, cloud computing systems, virtual computers, marine electronics devices, and the like.

The present techniques described herein may be implemented in distributed computing environments where tasks are performed by remote processing devices that are linked through a communications network, e.g., by hardwired links, wireless links, or various combinations thereof. In a distributed computing environment, program modules may be located in both local and remote computer storage media including, for example, memory storage devices and similar.

As an illustrative example, as shown in FIG. 8, one or more packaged chips 400, with the circuitry described above implemented on one chip or distributed over two or more of the chips, may be manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the circuitry described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e. small modular chips with particular functionality) may itself be referred to as a chip. A chiplet may be packaged individually in a semiconductor package and/or together with other chiplets into a multi-chiplet semiconductor package (e.g. using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g. plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc. ; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g. a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

As will be appreciated by one skilled in the art, the present technology may be embodied as a method, a circuit or a computer readable medium comprising data and imperatives to cause construction of a circuit. Accordingly, the present technique may take the form of an entirely hardware embodiment, an entirely software embodiment, or an embodiment combining software and hardware. Where the word “component” is used, it will be understood by one of ordinary skill in the art to refer to any portion of any of the above embodiments.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

In the present application, lists of features preceded with the phrase “at least one of” mean that any one or more of those features can be provided either individually or in combination. For example, “at least one of: [A], [B] and [C]” encompasses any of the following options: A alone (without B or C), B alone (without A or C), C alone (without A or B), A and B in combination (without C), A and C in combination (without B), B and C in combination (without A), or A, B and C in combination.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope of the invention as defined by the appended claims.

1. Storage circuitry comprising:
a bitcell array comprising a plurality of bitcells arranged in one or more columns and one or more rows;
a first bitline to select bitcells of a first column,
a first dummy bitline associated with the first bitline, where the first dummy bitline comprises dummy control circuitry having a plurality of electrical paths arranged between the dummy bitline and a first voltage level, where a first electrical path of the plurality of electrical paths comprises a first load electrically couplable thereto to control a property of a dummy bitline signal.

2. The storage circuitry of claim 1, wherein the dummy bitline signal is provided to dummy sensing circuitry to control signal generation at the dummy sensing circuitry.

3. The storage circuitry of claim 1, where the first load is programable.

4. The storage circuitry of claim 1, where the at least one electrical path is a discharge path between the dummy bitline and the first voltage level.

5. The storage circuitry of claim 1, where the at least one electrical path comprises a plurality of transistors arranged in series between the dummy bitline and the first voltage level.

6. The storage circuitry of claim 5, where at least one transistor is enabled responsive to a dummy wordline signal.

7. The storage circuitry of claim 6, where at least one transistor is enabled responsive to an extra margin adjustment (EMA) control signal.

8. The storage circuitry of claim 5, wherein the plurality of transistor components comprise NMOS transistors.

9. The storage circuitry of claim 1, where a second electrical path of the plurality of electrical paths comprises a plurality of transistors arranged in series between the dummy bitline and the first voltage level, and where the second electrical path is arranged in parallel with the first electrical path.

10. The storage circuitry of claim 1, where the second electrical path comprises a plurality of transistors arranged in series between the dummy bitline and the first voltage level.

11. The storage circuitry of claim 10, where the first electrical path comprising the first load is to control the property of the dummy bitline signal independently of the second electrical path.

12. The storage circuitry of claim 1, where the property comprises one or more of a discharge rate and slope of the dummy bitline signal.

13. The storage circuitry of claim 12, where the first load is to reduce the discharge rate and/or increase the slope of the dummy bitline signal.

14. The storage circuitry of claim 2, where the one or more signals from the dummy sensing circuitry are to control an access margin.

15. The storage circuitry of claim 1, wherein the first voltage level is a ground voltage level.

16. A method of operating storage circuitry, the storage circuitry including:
a bitcell array comprising a plurality of bitcells arranged in one or more columns and one or more rows;
a first bitline to select bitcells of a first column,
a first dummy bitline associated with the first bitline, where the first dummy bitline comprises dummy control circuitry having a plurality of electrical paths arranged between the dummy bitline and a first voltage level, where a first electrical path of the plurality of electrical paths comprises a first load electrically couplable thereto;
the method comprising: enabling the first electrical path to control a property of a dummy bitline signal.

17. A storage system comprising:
providing storage circuitry with a bitcell array comprising a plurality of bitcells arranged in one or more columns and one or more rows;
coupling a first bitline to the first column for selecting bitcells of a first column,
providing a first dummy bitline associated with the first bitline;
providing dummy control circuitry having a plurality of electrical paths arranged between the dummy bitline and a first voltage level, where a first electrical path of the plurality of electrical paths comprises a first load electrically couplable thereto to control a property of a dummy bitline signal.

18. A system comprising: the circuitry of claim 1, implemented in at least one packaged chip; at least one system component; and a board, wherein the at least one packaged chip and the at least one system component are assembled on the board.

19. A chip-containing product comprising the system of claim 18 assembled on a further board with at least one other product component.

20. A non-transitory computer-readable medium to store computer-readable code for fabrication of the circuitry claim 1.
